(19) United States
(12) Patent Application Publication
(10) Pub. No.: US 2016/0104672 A1
(43) Pub. Date: Apr. 14, 2016

(54) LOW CAPACITANCE BALLISTIC CONDUCTOR SIGNAL LINES

(71) Applicant: GLOBALFOUNDRIES Inc., Grand Cayman (KY)

(72) Inventors: Roderick A. Augur, Hopewell Junction, NY (US); Christian Witt, Woodbridge, CT (US)

(21) Appl. No.: 14/511,524

(22) Filed: Oct. 10, 2014

(51) Int. Cl. H01L 23/522; H01L 23/528; H01L 23/532; H01L 21/768

(52) U.S. Cl. CPC H01L 23/5225; H01L 21/76804; H01L 21/76834; H01L 23/5226; H01L 23/528; H01L 23/5329

(57) ABSTRACT

A method of electrically connecting first and second conductive features includes forming a first metallization layer including the first conductive feature. A ballistic conductor line is formed above the first metallization layer. The ballistic conductor line contacts the first conductive feature proximate a first end of the ballistic conductor line. The second conductive feature is contacted proximate a second end of the ballistic conductor line.

### BACKGROUND OF THE INVENTION

1. Field of the Invention

The disclosed subject matter relates generally to the fabrication of semiconductor devices and, more particularly, to forming low capacitance ballistic conductor signal lines.

2. Description of the Related Art

In modern integrated circuits, minimum feature sizes, such as the channel length of field effect transistors, have reached the deep sub-micron range, thereby steadily increasing performance of these circuits in terms of speed and/or power consumption and/or diversity of circuit functions. As the size of the individual circuit elements is significantly reduced, thereby improving, for example, the switching speed of the transistor elements, the available floor space for interconnect lines electrically connecting the individual circuit elements is also decreased. Consequently, the dimensions of these interconnect lines and the spaces between the metal lines have to be reduced to compensate for a reduced amount of available floor space and for an increased number of circuit elements provided per unit area.

Interconnect lines can be generally categorized into three groups: signal, clock and power lines. These interconnect types have different and, in some cases, opposing requirements. Signal lines require small capacitance and are less sensitive to resistance especially for short interconnects. Signal lines are almost immune from electromigration because they pass bidirectional currents. Thus, for signal lines, low aspect ratio lines are favored. Clock lines, which have an activity factor of 1, require low resistance and small capacitance. Clock lines, however, can fail due to electromigration because of the large currents they pass and because, in some cases, the current path is different in charge and discharge durations. Power lines are particularly susceptible to electromigration failure due to large currents flowing mainly in one direction.

In modern integrated circuits, a limiting factor of device performance is the signal propagation delay caused by the switching speed of the transistor elements. As the channel length of these transistor elements has now reached 50 nm and less, the signal propagation delay is no longer limited by the field effect transistors. Rather, the signal propagation delay is limited, owing to the increased circuit density, by the interconnect lines, since the line-to-line capacitance (C) is increased and also the resistance (R) of the lines is increased due to their reduced cross-sectional area. The parasitic RC time constants for signal lines limit the performance of the semiconductor devices.

Conventional dual damascene interconnect techniques typically result in lines having the same aspect ratio in a particular metallization layer. Hence, it is difficult to optimize the constructs of the lines depending on their intended function: signal, clock or power.

The present application is directed to various methods for low capacitance ballistic conductor interconnect lines so as to eliminate or reduce the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming conductive lines. One illustrative method of electrically connecting first and second conductive features includes forming a first metallization layer including the first conductive feature. A ballistic conductor line is formed above the first metallization layer. The ballistic conductor line contacts the first conductive feature proximate a first end of the ballistic conductor line. The second conductive feature is contacted proximate a second end of the ballistic conductor line.

An illustrative device includes a first dielectric layer, a first conductive feature embedded in the first dielectric layer, a second dielectric layer formed above the first dielectric layer and a second conductive feature embedded in one of the first dielectric layer or the second dielectric layer. A ballistic conductor line is embedded in the second dielectric layer and contacts the first and second conductive features.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1G are cross-sectional diagrams depicting illustrative techniques for forming low capacitance ballistic conductor lines in an interconnect structure; and

FIG. 2 is a cross-sectional diagram along a length of an exemplary low capacitance ballistic conductor line illustrating an alternative structure for forming interconnections between conductive features using the ballistic conductor line.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase. The present disclosure is directed to various methods of forming an interconnect structure. With reference to the attached drawings various illustrative embodiments of the methods and devices disclosed herein will now be described in more detail.

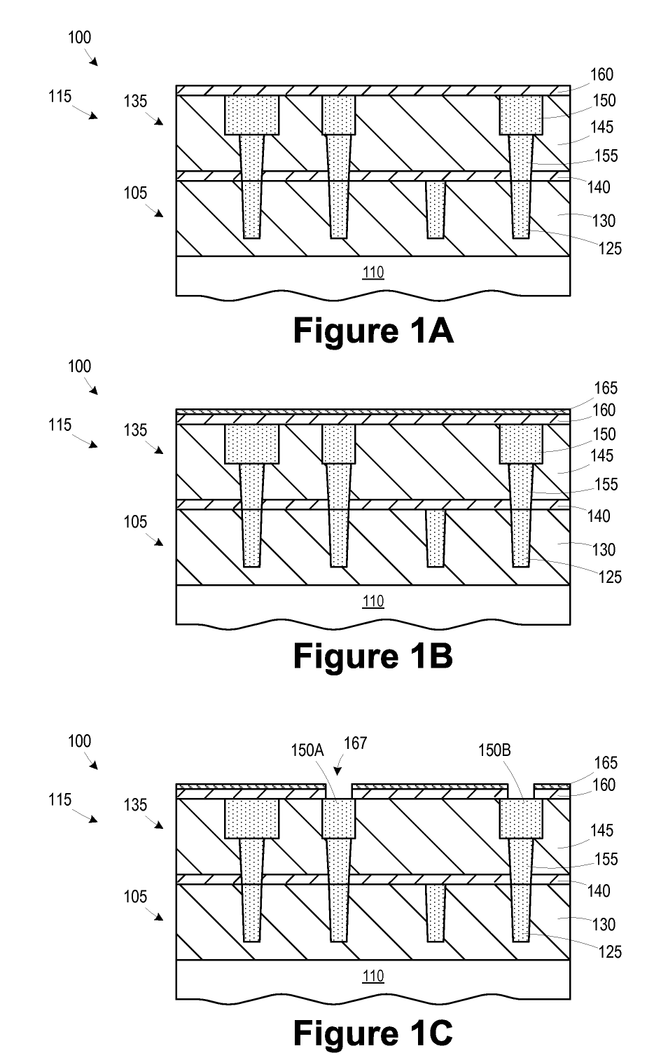

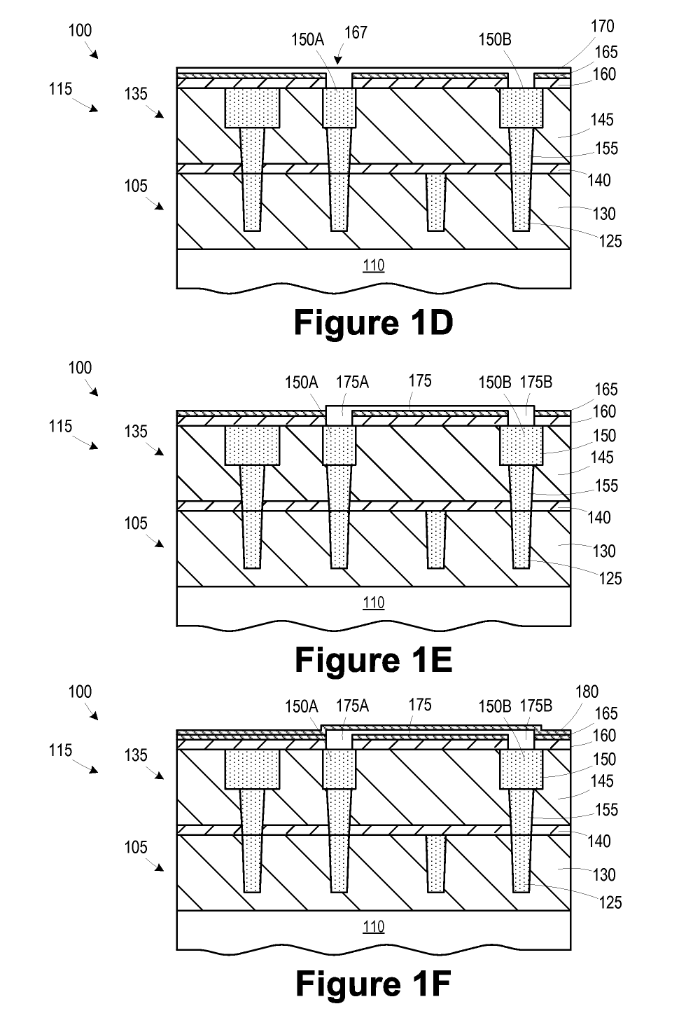

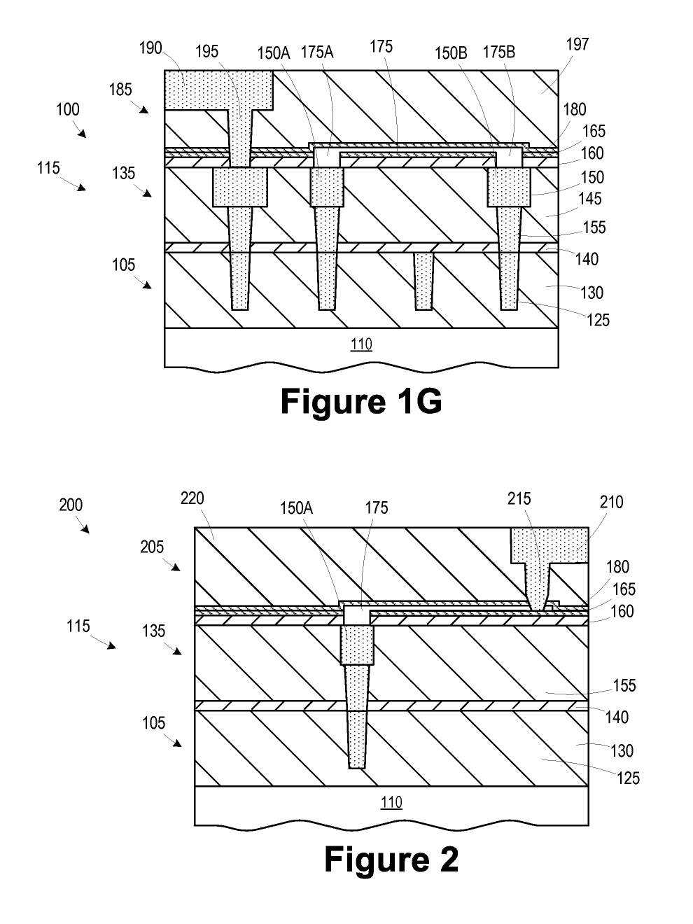

FIGS. 1A-1G are cross-sectional diagrams illustrating a method for forming low capacitance signal lines in a semiconductor device 100, which, in the present embodiment, may be represented by an integrated circuit including circuit elements, such as transistors, capacitors, resistors and the like. FIG. 1A illustrates the device 100 including a device layer 105 formed in and above a substrate 110 in which semiconductor-based circuit elements may be provided. For convenience, any such circuit elements are not shown in FIG. 1A. The substrate 110 may also include any appropriate microstructure features, such as micromechanical components, optoelectronic components and the like, wherein at least some of these components may require an interconnect structure formed in a metallization system 115. In highly complex integrated circuits, a very large number of electrical connections may be required and, thus, a plurality of metallization layers may typically be formed in the metallization system 115.

The device layer 105 includes contacts 125 (e.g., tungsten) formed in a dielectric layer 130 for contacting underlying devices, such as transistors (not shown). A first metallization layer 135 (sometimes referred to in the industry as the “M1” or “metal 1” layer) of the metallization system 115, including a cap layer 140 (e.g., SiCN) and a dielectric layer 145, is formed above the device layer 105. The first metallization layer 135 is formed using a conventional dual damascene process to define conductive lines 150 (e.g., copper) to provide intra-layer signal paths and vias 155 (e.g., copper) to provide inter-layer signal paths. A cap layer 160 (e.g., SiCN) is formed above the dielectric layer 145.

The dielectric layers 130, 145 may be the same or different materials. In the illustrated embodiment, the dielectric layer 145 may be a low-k dielectric material having a dielectric constant of approximately 3.0 or lower or an ultra-low-k (ULK) material having a dielectric constant of approximately 2.5 or lower.

FIG. 1B illustrates the device 100 after a first deposition process is performed to form a cladding layer 165 (e.g., boron nitride) above the cap layer 160. FIG. 1C illustrates the device 100 after several processes are performed to define an opening 167 in the cladding layer 165 and the cap layer 160 to expose at least one of the conductive features in the first metallization layer 135, such as a particular conductive line 150A. In some embodiments, the conductive feature may be a different type of feature, such as a via. The opening 167 may be formed by depositing a mask layer (e.g., photoresist or patterned hard mask—not shown) and patterning the mask layer to define an opening above the cladding layer 165. An etch process (e.g., an anisotropic reactive ion etch (RIE)) is performed in the presence of the mask layer to define the opening 167.

FIG. 1D illustrates the device 100 after a second deposition process is performed to form a ballistic conductor layer 170 above the cladding layer 165 and in the opening 167 such that the ballistic conductor layer 170 is conductively coupled to the line 150A. The ballistic conductor layer 170 is formed from a material that exhibits ballistic conduction, also referred to as ballistic transport, where the transport of electrons occurs in a medium having negligible electrical resistivity caused by scattering. In contrast, a conventional Ohmic conductor material has a resistivity value that is in large part defined by the degree of scattering within the material. In some embodiments, the ballistic conductor layer 170 may include a plurality of layers of ballistic conductor material formed in a stack. In other embodiments, a stack may be formed by alternating layers of ballistic conductor material and cladding material.

Exemplary ballistic conductor materials include graphene, carbon nanotubes, silicon nanowires, samarium hexaboride, stanene, silicene, boronene and topolocial insulators, such as mercury telluride, cadmium telluride, bismuth antimonide, pure antimony, bismuth selenide, bismuth telluride and antimony telluride. In general, ballistic conductor materials provide low-capacitance signal paths with very thin material layers. In general, ballistic conductor materials may be formed in very thin sheets, sometime as thin as the thickness of a single atom. The manner in which such ballistic conductor materials may be formed is known to those skilled in the art.

FIG. 1E illustrates the device 100 after a patterning process including multiple steps has been performed to pattern the ballistic conductor layer 170 to define a ballistic conductor line 175. The ballistic conductor line 175 may be formed by depositing a mask material (e.g., photoresist or patterned hard mask), patterning the mask material using a photolithography process, and etching the ballistic conductor layer 170 (e.g., CF₄/O₂ reactive ion etch) exposed by the mask material to define the ballistic conductor line 175. The ballistic conductor line 175 extends along the surface of the cladding layer 165 and has downward extending via portions 175A, 175B that contact the underlying conductive features 150A, 150B through the cap layer 160 and the cladding layer 165.

FIG. 1F illustrates the device 100 after performing a deposition process to form a second cladding layer 180 (e.g., boron nitride) above the ballistic conductor line 175.

FIG. 1G illustrates the device 100 after performing a plurality of processes to define a second metallization layer 185 of the metallization system 115 above the first metallization layer 135. The second metallization layer 185 includes a conductive line 190 and a via 195 embedded in a dielectric layer 197. The terms “first” and “second” with respect to the metallization layers are used to distinguish between the layers rather than to imply a particular spatial relationship. The device layer 105 also includes interconnect features, and it may also be considered a metallization layer within the metallization system 115. The ballistic conductor line 175 forms a signal path between the conductive feature 150A at one end and the second conductive feature 150B at the other end. In the example of FIG. 1G, the second conductive feature 150B is formed in the first metallization layer 135. The RC product associated with the ballistic conductor line 175 is independent from the RC product of the other conductive lines in the metallization layers 135, 185. The conductive feature 150A may be associated with a sender of a signal, such as a logic signal or a clock signal, and the conductive feature 150B may be associated with a receiver of the signal.

FIG. 2 illustrates an alternative embodiment of a device 200 along a length of the ballistic conductor line 175 after performing a plurality of processes to define a second metallization layer 205 of the metallization system 115 above the first metallization layer 135. The second metallization layer 205 includes a conductive line 210 and a via 215 embedded in a dielectric layer 220. In this embodiment, the ballistic conductor line 175 forms a signal path between the conductive feature 150A at one end and the via 215 at the other end. The second metallization layer 205 may be formed using a conventional dual damascene process flow to define the conductive line 210 and the via 215.

The sidewall angle of the via 215 may affect the quality of the connection between the via 215 and the ballistic conductor line 175. The etch process for forming the openings in the cladding layer 180 and the ballistic conductor line 175 prior to forming the via 215 may be tailored to increase the sidewall angle, at least in the region where the via 215 interfaces with the ballistic conductor line 175.

The use of ballistic conductor signal lines 175 within the metallization layers 135, 185, 205 allows both low aspect ratio signal or clock lines and high aspect ratio power lines to coexist. The RC characteristics of the lines may be controlled separately, thereby allowing separate optimization of the line characteristics.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of electrically connecting first and second conductive features, the method comprising:
forming a first metallization layer comprising said first conductive feature;
forming a ballistic conductor line above said first metallization layer, said ballistic conductor line contacting said first conductive feature proximate a first end of said ballistic conductor line; and
contacting said second conductive feature proximate a second end of said ballistic conductor line.

2. The method of claim 1, wherein said second conductive feature is defined in said first metallization layer, said ballistic conductor line forming a signal path between said first and second conductive features.

3. The method of claim 1, further comprising:
forming a cap layer above said first metallization layer; and
patterning said cap layer to expose said first conductive feature, wherein forming said ballistic conductor line comprises forming said ballistic conductor line above said cap layer.

4. The method of claim 1, further comprising:
forming a dielectric layer above said ballistic conductor line; and
embedding a first via in said dielectric layer, said first via comprising said second conductive feature to define a signal path between said first conductive feature and said via.

5. The method of claim 4, wherein said first via comprises tapered sidewalls.

6. The method of claim 5, wherein said tapered sidewalls have an increased taper in at least a region of the sidewalls interfacing with said ballistic conductor line.

7. The method of claim 1, wherein said first conductive feature comprises a conductive line.

8. The method of claim 1, further comprising forming a cladding layer surrounding said ballistic conductor line.

9. The method of claim 1, further comprising:
forming a first cladding layer above said first metallization layer;
patterning said cladding layer to expose said first conductive feature;
forming a ballistic conductor layer above said first cladding layer to contact said first conductive feature;
patterning said ballistic conductor layer to define said ballistic conductor line; and
forming a second cladding layer above said ballistic conductor line.

10. The method of claim 1, wherein forming said ballistic conductor line comprises:
forming a stack comprising alternating layers of ballistic conductor material and a cladding material; and
patterning said stack to define said ballistic conductor line.

11. A device, comprising:
a first dielectric layer;
a first conductive feature embedded in said first dielectric layer;
a second dielectric layer formed above said first dielectric layer;
a second conductive feature embedded in one of said first dielectric layer or said second dielectric layer; and
a ballistic conductor line embedded in said second dielectric layer and contacting said first and second conductive features.

12. The device of claim 11, wherein said second conductive feature is defined in said first dielectric layer.

13. The device of claim 11, further comprising a cap layer formed between said first and second dielectric layers, said cap layer having an opening defined therein to allow said ballistic conductor line to contact said first conductive feature.

14. The device of claim 11, wherein said second conductive feature comprises a via embedded in said second dielectric layer.

15. The device of claim 14, wherein said via comprises tapered sidewalls.

16. The device of claim 15, wherein said tapered sidewalls have an increased taper in at least a region of the sidewalls interfacing with said ballistic conductor line.

17. The device of claim 11, wherein said first conductive feature comprises a conductive line.

18. The device of claim 11, further comprising a cladding layer surrounding said ballistic conductor line.

19. The device of claim 18, wherein said cladding layer comprises boron nitride.

20. The device of claim 11, wherein said ballistic conductor line comprises a stack comprising alternating layers of ballistic conductor material and a cladding material.
